(19) United States
(12) Patent Application Publication
(10) Pub. No.: US 2026/0214894 A1
(43) Pub. Date: Jul. 23, 2026

(54) NON-VOLATILE MEMORY INTEGRATED CIRCUIT AND CORRESPONDING MANUFACTURING METHOD

(71) Applicant: STMicroelectronics International N.V., Geneva (CH)

(72) Inventors: Michele Calvo, Grenoble (FR); Stephan Niel, Meylan (FR); Francesco La Rosa, Rousset (FR)

(21) Appl. No.: 19/455,442

(22) Filed: Jan. 21, 2026

(30) Foreign Application Priority Data
Jan. 23, 2025 (FR) FR2500702

(51) Int. Cl. H10B 41/35; G11C 16/04; G11C 16/10

(52) U.S. Cl. CPC H10B 41/35; G11C 16/0425; G11C 16/10; G11C 2216/04

(57) ABSTRACT

The non-volatile memory integrated circuit comprises memory cells including a state transistor having a control gate, a floating gate, and an erase gate, and a transistor for selecting a vertical gate buried in a semiconductor substrate.

### CROSS-REFERENCE TO RELATED APPLICATIONS

This application claims the benefit of French Application No. 2500702, filed on Jan. 23, 2025, which application is hereby incorporated by reference herein in its entirety.

### TECHNICAL FIELD

Embodiments and implementations relate to non-volatile memory integrated circuits and methods for manufacturing the integrated circuits.

### BACKGROUND

A non-volatile memory technology, usually called “Super-Flash”, includes memory cells provided with a floating gate state transistor, in series with a select transistor (or gate), and further including an erase gate opposite to the floating gate.

In Super-Flash technology, programming and erase operations implement charge transfers (injections and extractions) through different gate dielectric layers, which makes it possible in particular to benefit from less wear of the gate dielectrics and good data retention. On the other hand, the use of the erase gate dedicated to erase operations makes it possible to benefit from a good efficiency of erase operations. A notable drawback of conventional Super-Flash technologies is a relatively large footprint.

Another non-volatile memory technology, usually called “eSTM” (for “embedded Select Trench Memory”), includes memory cells provided with a floating gate state transistor in series with an buried vertical gate select transistor.

The eSTM technology benefits in particular from a very small surface footprint, in particular due to the arrangement of the select transistor; and from improved efficiency of the programming operations, in summary due to a vertical circulation of the charges injected into the floating gate. However, eSTM technology does not have as good data retention performance as SuperFlash technology.

There is a need to improve either of the aforementioned technologies to preserve or amplify the advantages of each and to mitigate or address its drawbacks.

### SUMMARY

According to one aspect, a non-volatile memory integrated circuit is proposed in this respect, comprising at least two memory cells, each of them including a state transistor having a control gate, a floating gate and an erase gate, and a vertical gate select transistor buried in a semiconductor substrate.

Furthermore, the select transistor is common to the two state transistors arranged on either side of the vertical gate, and the erase gate is common to the two state transistors arranged on either side of the erase gate.

In other words, the select transistor, distinct from the two state transistors, is shared by (common to) the two state transistors, which are arranged on either side of the select transistor. Moreover, an erase gate is shared by (common to) the two state transistors arranged on either side of the erase gate.

The memory cell structure according to this aspect thus makes it possible to implement transfers (injections and extractions) of charges through different dielectric layers during programming and erase operations, and to benefit from less wear of the dielectric layers and consequently from a high performance in terms of data retention. The memory cell structure according to this aspect further benefits from both good efficiency of the erase operations thanks to the use of the erase gate, and good efficiency of the programming operations thanks to a vertical circulation of the charges injected into the floating gate, passing through the select transistor.

The memory cell structure according to this aspect also benefits from a very small surface footprint due to the arrangement of the select transistor, and more specifically thanks to the sharing of the select transistor and the erase gate for the two state transistors of the memory cells.

The memory cell structure is consequently more compact. This makes it possible to significantly reduce the circuit size and to increase cell density. In addition, this symmetrical arrangement and the sharing of the erase and vertical gates limit electrical variations between adjacent memory cells, thereby improving the uniformity of programming and erasing operations. The use of common erase and vertical gates also reduces the number of active components required, which may lead to lower power consumption.

According to one embodiment, the vertical gate of the select transistor and the shared erase gate of the state transistor are superimposed.

According to one embodiment, the shared erase gate is located between the two control gates of the state transistors and between the two floating gates of the state transistors.

According to one embodiment, the two memory cells are symmetrical to each other with respect to a plan passing through the shared erase gate and vertical gate.

According to one embodiment, the control gate is disposed above the floating gate and the erase gate is disposed laterally opposite to the floating gate, the gate structure of the state transistor being disposed above a front face of the semiconductor substrate; and the buried vertical gate select transistor is disposed in the semiconductor substrate below the front face.

According to one embodiment, the floating gate is bordered by a first dielectric layer opposite to the semiconductor substrate, and by a second dielectric layer opposite to the erase gate.

Being distinct, the first dielectric layer can be designed optimally with regard to programming operations, for example, and the second dielectric layer can be designed optimally with regard to erase operations, for example.

In addition to making optimal operations possible, the dielectric layers each benefit from less wear, advantageously in terms of data retention.

According to one embodiment, the vertical gate of the select transistor and the erase gate of the state transistor have vertically aligned positions and are electrically separated by a dielectric thickness.

Such an arrangement makes it possible not to occupy additional surface to position the select transistor relative to the erase gate; or vice versa to position the erase gate relative to the select transistor.

According to one embodiment, the vertical gate of the select transistor includes polycrystalline silicon doped with a concentration which is greater than 1019 cm-3 for example.

This advantageously makes it possible to compensate for or protect against an increase in the resistivity of the vertical gate caused by difficulties in forming a metal silica film in the vertical gate, due to the arrangement of the erase gate covering the vertical gate. The high concentration of dopants makes it possible to lower the resistivity of the vertical gate and consequently not to degrade the memory access time, which is a feature related to resistivity.

According to one embodiment, the memory cells are arranged in a memory plane, traversed in a first direction by bit lines coupled to drain regions of the state transistors; and traversed in a second direction by control gate lines comprising the control gates of the state transistors, erase lines comprising the erase gates of the state transistors, and word lines comprising the vertical gates of the select transistors.

According to one embodiment, the control gate lines further comprise metal tracks for routing the erase and programming control signals and control gate line contact sockets coupling the control gate with the metal tracks; the erase lines further comprise metal tracks for routing the erase control signals and erase line contact sockets coupling the erase gates with the metal tracks; the word lines further comprise metal tracks for routing the control signals of the select transistors and word line contact sockets coupling the vertical gates with the metal tracks.

The coupling of the vertical gates with metal tracks advantageously makes it possible to compensate for a greater resistivity of the vertical gates because they do not include a metal silicon region, in the distribution and routing of the erase and programming control signals. The word line contacts cause interruptions, in the second direction, of the erase gates, again due to the arrangement of the erase gates covering the vertical gates. The coupling of the erase gate with the metal tracks ensures the electrical continuity of the erase gate for the distribution and routing of the erase control signals.

According to one embodiment, the word line contact sockets are periodically disposed in the first direction with a first deviation; the erase line contact sockets are periodically disposed in the first direction with the first deviation; the control gate line contact sockets are periodically disposed in the first direction with a second deviation; the first deviation being 3 to 5 times smaller than the second deviation.

The second deviation, for example of 37 μm, is in particular suitable, from the point of view of memory access time, for a region made of polycrystalline silicon including a metal silicide film. While the first deviation, for example of 9 μm, is in particular suitable, from the point of view of memory access time, for a region made of polycrystalline silicon not including a metal silicide film.

According to one embodiment, the integrated circuit further comprises write circuit configured to control, in the memory cells, a programming operation capable of injecting electrical charges circulating through a channel region of the select transistor, into the floating gate of the state transistor; and an erase operation capable of extracting electrical charges from the floating gate to the erase gate.

According to one embodiment, the write circuit is configured to control, in the programming operation, the injection of charges into the floating gate by hot carrier effect; and, in the erase operation, the extraction of charges from the floating gate by Fowler-Nordheim effect.

The mechanisms for injecting and extracting charges defined according to these embodiments correspond to the optimal mechanisms in terms of the efficiencies of the programming and erase operations.

According to another aspect, a method is proposed for manufacturing a non-volatile memory integrated circuit including at least two memory cells, the method comprising for manufacturing the memory cells: steps of forming a vertical gate select transistor buried in a semiconductor substrate; steps of forming a state transistor having a control gate and a floating gate; and steps of forming an erase gate of the state transistor; the select transistor being common to said two state transistors arranged on either side of the vertical gate, and the erase gate being common to said two state transistors arranged on either side of the erase gate.

According to one implementation: the steps of forming the vertical gate select transistor comprise etching a trench extending vertically in the semiconductor substrate below a front face of the substrate; the steps of forming the state transistor comprise forming the floating gate above the front face of the substrate, forming the control gate above the floating gate; the steps of forming the erase gate of the state transistor comprise positioning the erase gate laterally opposite to the floating gate, above the front face of the semiconductor substrate.

According to one implementation: the steps of forming the state transistor comprise forming a first dielectric layer, bordering the floating gate opposite to the substrate;-the steps of forming the erase gate of the state transistor comprise forming a second dielectric layer, bordering the floating gate opposite to the erase gate.

According to one implementation: the steps of forming the erase gate of the state transistor comprise forming a dielectric thickness electrically separating the erase gate and the vertical gate of the select transistor, the erase gate being aligned vertically on the vertical gate.

According to one implementation: the steps of forming the select transistor comprise forming the vertical gate with polycrystalline silicon doped with a concentration which is greater than 1019 cm-3 for example.

According to one implementation, the memory cells are arranged in a memory plane, and the method further comprises: steps of forming bit lines coupled to drain regions of the state transistors, traversing the memory plane in a first direction; control gate line formations comprising the control gates of the state transistors, erase line formations comprising the erase gates of the state transistors, and word line formations comprising the vertical gates of the select transistors, traversing the memory plane in a second direction.

According to one implementation, the formations of the control gate lines further comprise metal tracks for routing the erase and programming control signals and control gate line contact sockets coupling the control gates with said metal tracks; the erase line formations further comprise metal tracks for routing the erase control signals and erase line contact sockets coupling the erase gates with said metal tracks; the word line formations further comprise metal tracks for routing the control signals of the select transistors and word line contact sockets coupling the vertical gates with said metal tracks.

According to one implementation, the word line contact sockets are periodically formed in the first direction with a first deviation; the erase line contact sockets are periodically formed in the first direction with the first deviation; the control gate line contact sockets are periodically formed in the first direction with a second deviation; the first deviation being 3 to 5 times smaller than the second deviation.

According to one implementation, further comprising, by means for writing in the memory cells: a programming operation injecting electrical charges circulating through a channel region of the select transistor, into the floating gate of the state transistor; and an erase operation extracting electrical charges from the floating gate to the erase gate.

According to one implementation, the programming operation injects charges into the floating gate by hot carrier effect; and, the erase operation extracts charges from the floating gate by Fowler-Nordheim effect.

### BRIEF DESCRIPTION OF THE DRAWINGS

Other advantages and features of the invention will appear upon examining the detailed description of non-limiting embodiments and implementations, without limitation, and from the appended drawings, wherein:

FIG. 1 illustrates an example of memory cells, in a cross-sectional view of a semiconductor portion of a non-volatile memory integrated circuit;

FIG. 2A illustrates a programming operation controlled by write circuit of the integrated circuit;

FIG. 2B illustrates an erase operation controlled by write circuit of the integrated circuit;

FIG. 3A shows a top view, in a plane XY, of the memory plane at a position of a contact socket of a word line;

FIG. 3B illustrates a sectional view of the memory plane, in the plane YZ marked by the axis 33 in FIG. 3A passing through the word line contact;

FIG. 4A shows a top view, in a plane XY, of the memory plane at a position of a contact socket of an erase line;

FIG. 4B illustrates a sectional view of the memory plane, in the plane YZ marked by the axis 44 in FIG. 4A passing through the erase line contact;

FIG. 5A shows a top view, in an XY plane, of the memory plane at a position of a contact socket of a control gate line;

FIG. 5B illustrates a sectional view of the memory plane, in the plane YZ marked by the axis 5 in FIG. 5A passing through the control gate line contacts; and

FIG. 6 illustrates a method for manufacturing the non-volatile memory integrated circuit including memory cells as previously described in relation to FIGS. 1 to 5B.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

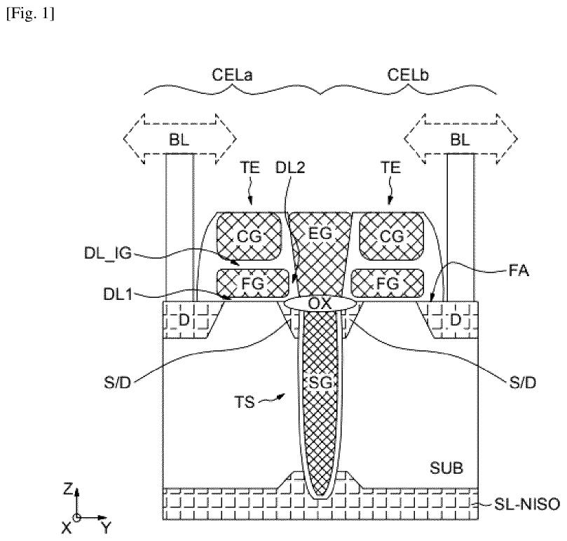

FIG. 1 illustrates an example of memory cells CELa, CELb, in a cross-sectional view of a semiconductor portion (usually called “FEOL” for “Front End Of Line”) of a non-volatile memory integrated circuit.

The semiconductor portion “FEOL” usually denotes the portion including the semiconductor components, in particular the transistors, made from a face called front face FA of a semiconductor substrate SUB typically made of P-type silicon. The front face FA is perpendicular to a vertical direction Z, oriented such that “below” (i.e. vertical direction in negative orientation) of the face FA is the substrate SUB, and “above” (i.e. vertical direction in positive orientation) of the front face FA are metal levels of a portion of interconnections (usually called “BEOL” for “Back End Of Line”) of the integrated circuit.

The memory cells CELa, CELb each include a state transistor TE including a control gate CG, a floating gate FG and an erase gate EG, coupled in series with a buried vertical gate select transistor TS.

The two memory cells CELa, CELb are adjacent and symmetrical to each other, and have in common the select transistor TS and the erase gate EG. In other words, the select transistor TS is common to the two state transistors TE, which are arranged on either side of the vertical gate SG. Moreover, the erase gate EG is common to the two state transistors TE arranged on either side of the erase gate EG. The two adjacent memory cells CELa, CELb are symmetric to each other by a plane passing through the common erase gate EG and vertical gate SG.

The select transistor TS is buried in the semiconductor substrate SUB below the front face FA and includes a vertical gate SG sinking deep into the substrate SUB, until substantially reaching a conduction region SL-NISO implanted deep in the substrate SUB. It is located between the two state transistors TE of the memory cells CELa, CELb.

The serial coupling of the state transistor TE and the select transistor TS, node-to-node, ranges from the drain region D of the state transistor TE coupled to a bit line BL, to an S/D conduction region common to the state transistor TE (source) and the select transistor TS (drain), to the conduction region SL-NISO (source) implanted deep, the latter acting as the source line or source plane SL-NISO.

The state transistor TE includes a control gate CG, a floating gate FG, as well as in addition a common erase gate EG. The control gate CG is disposed above the floating gate FG, itself above the front face FA, opposite to the substrate SUB. The common erase gate EG is disposed laterally opposite to the floating gate FG, also above the front face FA and for example up to the height of the control gate CG.

The control gate CG, floating gate FG and common erase gate EG of the state transistor TE, as well as the vertical gate SG of the select transistor TS are electrically conductive and usually include doped polycrystalline silicon, and possibly metals.

The floating gate FG is bordered (or framed) by thicknesses of dielectric material, typically silicon oxide, in order to be electrically isolated from the rest of the circuit, and to maintain a floating potential.

In particular, the floating gate FG is bordered by a first dielectric layer DL1 opposite to the semiconductor substrate SUB, and by a second dielectric layer DL2 opposite to the common erase gate EG.

Thus, the first dielectric layer DL1 is located between the floating gate FG and the substrate SUB, while the second dielectric layer DL2 is located between the floating gate FG and the common erase gate EG. Moreover, an inter-gate dielectric layer DL_IG is usually disposed between the floating gate FG and the control gate CG and includes, for example, a stack of silicon oxide-nitride-oxide layers.

For example, the thickness of the first dielectric layer DL1, in the vertical direction Z, may be comprised between 5 nm and 15 nm.

For example, the thickness of the second dielectric layer DL2, in the horizontal direction Y, may be comprised between 10 nm and 20 nm.

Furthermore, the thickness of the inter-gate dielectric layer DL_IG, in the vertical direction Z, may be comprised between 10 nm and 20 nm.

In an architecture advantageously for reducing the footprint of the memory cells CELa, CELb, the select transistor TS is shared for two state transistors TE on either side (in the Y direction) of the vertical gate SG; similarly, the erase gate EG is shared for the two state transistors TE on either side (in the Y direction) of the erase gate EG.

Thus, in this respect, the vertical gate SG of the select transistor TS and the erase gate EG of the state transistor TE are superimposed, that is to say the positions thereof are aligned in the vertical direction Z.

The common erase gate EG is located between the two control gates CG and between the two floating gates FG of the state transistors TE.

The erase gate EG is arranged at the same vertical level as the control gate CG and the floating gate FG of the state transistors TS. The vertical gate SG is buried in the substrate and is superimposed beneath the erase gate EG, such that the vertical gate SG is located at a lower vertical level than the control gate CG and the floating gate FG. The control gate CG and the floating gate FG are laterally arranged on opposite sides of the vertical gate SG and are positioned above the vertical gate SG.

A thickness of dielectric material OX, for example silicon oxide or optionally a stack of oxide-nitride-silicon oxide, is provided to ensure an electrical separation between the erase gate EG and the vertical gate SG.

On the other hand, the superimposition of the erase gate EG covering the vertical gate SG can cause difficulties in implementing a silicidation reaction, that is to say a formation of a layer or film of metal silicide, typically provided at the end of the method for manufacturing the “FEOL” on surfaces left open and exposed in this respect.

A lack of silicidation can cause the resistivity of the conductive material of the vertical gate to be higher than a nominal value. This can result in a loss of performance in terms of access time to memory cells. In order to compensate for or protect against such a loss of performance, the vertical gate SG advantageously includes polycrystalline silicon doped with a concentration greater than 1019 cm-3, for example.

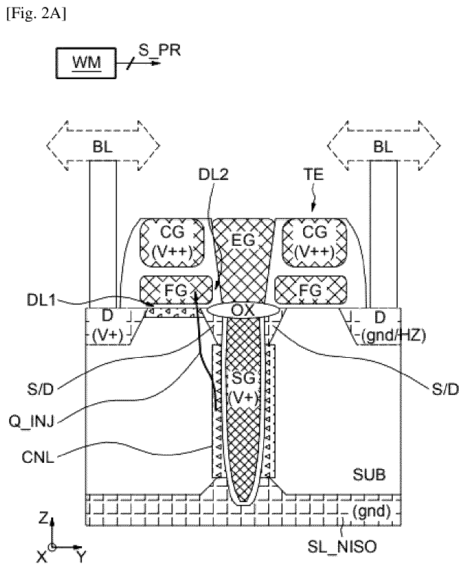

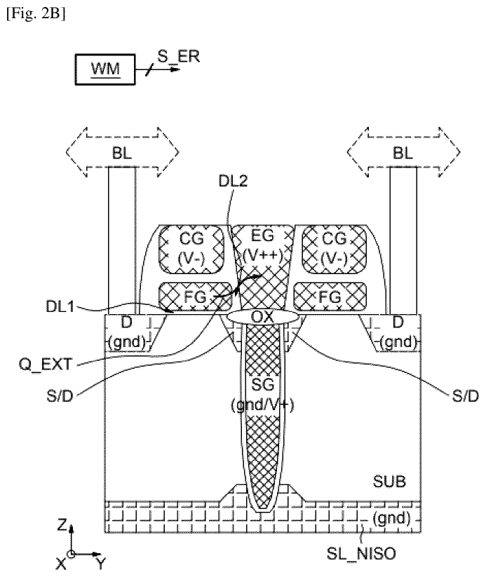

Reference is now made to FIGS. 2A and 2B which schematically illustrate implementations of programming and erase operation in a memory cell CELa of the memory integrated circuit which is previously described in relation to FIG. 1.

FIG. 2A illustrates a programming operation S_PR controlled by write circuit WM of the integrated circuit.

The write circuit WM are configured to distribute control signals S_PR in the memory cells in order to generate an injection of electrical charges Q_INJ into the floating gate FG of the state transistor TE.

In particular, the injection of charges Q_INJ into the floating gate FG exploits the generation effect of “hot carriers”, in summary electrical charges (e.g. electrons) with high kinetic energy, able to pass from the substrate SUB to the floating gate FG through the first dielectric layer DL1.

In this respect, the programming control signals S_PR may be provided to: polarise the control gates CG to a positive high voltage V++, for example 10 V, causing the formation of a conductive channel CNL under the floating gate FG; polarise the common vertical gate SG to a positive selection voltage V+, for example 2 V, so as to form a vertical conductive channel CNL along the common vertical gate SG; polarise the drain region D, via the bit line BL, to a positive selection voltage V+, for example 4 V, and the source line SL-NISO to the ground gnd; place the unselected BL bit lines at a ground voltage or high impedance gnd/HZ.

Under these conditions, a current flows from the bit line BL to the source line SL-NISO through the conductive channel regions CNL, (which corresponds to an electron flow in the opposite direction). This electron flow contains “hot” electrons with high kinetic energy (hot electrons) that are injected into the floating gate FG through the first dielectric layer DL1. Once injected into the floating gate FG, the charges are “trapped” as floating potential, causing a version of the threshold voltage of the state transistor TE corresponding to a programmed state of a bit.

Furthermore, in a simplified example, the state transistor TE of the neighbouring memory cell CELb is controlled with zero voltages (gnd), in particular on the control gate CG and the drain D thereof, such that it does not undergo any parasite programming process; nor any of the other read transistors of the memory plane, which receive only zero voltages (gnd).

The mechanism for injecting hot carriers Q_INJ circulating through the vertical channel region CNL of the select transistor TS and through the first dielectric layer DL1 with a substantially perpendicular incidence, corresponds to an optimal mechanism in terms of the efficiency of the programming operation.

Optimum efficiency may for example result in the use of lower programming high voltages, and/or shorter programming times, and/or a larger amount of injected charge.

FIG. 2B illustrates an erase operation S_ER controlled by write circuit WM of the integrated circuit.

The write circuit WM are configured to distribute control signals S_ER in the memory cells in order to generate an extraction of electrical charges Q_EXT contained in the floating gate FG of the state transistor TE.

In particular, the extraction of charges Q_EXT from the floating gate FG exploits the “Fowler-Nordheim” effect, in summary an electrical field capable of generating a displacement by “tunnel effect” of the electrical charges from the floating gate FG through the second dielectric layer DL2.

In this respect, the erase control signals S_ER may be provided to: polarise the common erase gate EG to a positive erase voltage V++, for example +10 V; polarise the control gates CG to a negative erase voltage V−, for example −4 V; polarise the common vertical gate SG to a stress management voltage, for example, either to the ground gnd, or to a slightly positive voltage, following a compromise between the stress of the vertical gate relative to the floating gate FG and the stress between the common vertical gate EG and the common erase gate EG; polarise the other nodes (D-drains and BL bit lines, from SL_NISO source) to ground gnd.

Under these conditions, the negative charges (electrons) contained in the floating gate FG of the erased memory cell CELa are extracted through the second dielectric layer DL2, by Fowler-Nordheim effect, and discharged into the common erase gate EG.

The Fowler-Nordheim extraction mechanism Q_EXT to the common erase gate EG and through the second dielectric layer DL2, corresponds to an optimal mechanism in terms of the efficiency of the erase operation.

The optimum efficiency may for example result in the use of lower erase voltages, and/or shorter erase times, and/or a greater amount of extracted charges.

It should be noted that the injection of electrical charges Q_INJ of the programming operation is made through the first dielectric layer DL1 (FIG. 2A), distinctly from the extraction of electrical charges Q_EXT of the erase operation, made through the second dielectric layer DL2 (FIG. 2B).

Thus, the thicknesses and the materials of the first dielectric layer DL1 and of the second dielectric layer DL2 can be optimally chosen for the respective programming operation or erase operation, without being subject to the constraints of the other operation. In this respect, it will be possible, for example, to provide, for the first dielectric layer DL1, a silicon dioxide thickness comprised between 5 nm and 15 nm and, for the second dielectric layer DL2, a silicon dioxide thickness comprised between 10 nm and 20 nm.

Furthermore, the ageing of the memory cells is delayed because the first dielectric layer DL1 and the second dielectric layer DL2 each benefit from less wear. This results in high memory performance in terms of data retention.

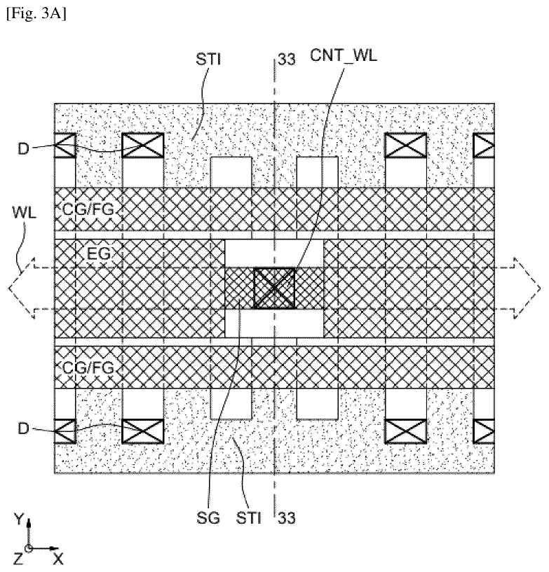

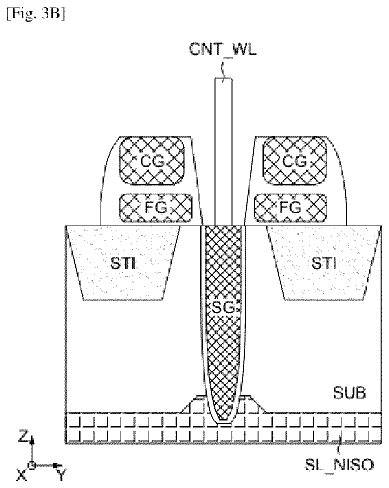

Reference is now made to FIGS. 3A, 3B, 4A, 4B, 5A, 5B which schematically illustrate access lines WL, EL, CGL for routing according to certain selectivites the programming and erase signals, in the memory cells thus arranged in a memory plane.

The memory plane is traversed in a first direction Y by the bit lines BL (not represented) coupled to the drain regions D of the state transistors TE, as described above in relation to FIG. 1, and 2A, 2B. The access lines WL, EL, CGL, described below, traverse the memory plane in the second direction X. Thus, decoding in X and Y makes it possible to selectively access potentially each memory cell of the memory plane.

In FIGS. 3A to 5B and in FIGS. 1 to 2B, the same references designate the same elements, the latter will not be detailed again.

FIG. 3A shows a top view, in a plane XY, of the memory plane at a position of a contact socket CNT_WL of a word line WL.

The word lines WL are for example materialised by the vertical gates SG of the select transistors, traversing the memory plane in a second direction X, in a mutualised manner for a group of memory cells, called memory word.

The memory cells are spaced apart from each other by lateral isolation regions STI, for example of the shallow isolation region type.

FIG. 3B illustrates a sectional view of the memory plane, in the plane YZ marked by the axis 33 in FIG. 3A passing through the word line contact CNT_WL.

The word line contact sockets CNT_WL, for example, are metal pillars for connecting the vertical gate SG to metal tracks of the “BEOL” interconnection levels, to route the control signals of the select transistors TS.

For example, the word line contact sockets CNT_WL may be disposed every 9 μm (micrometres) in the second direction X.

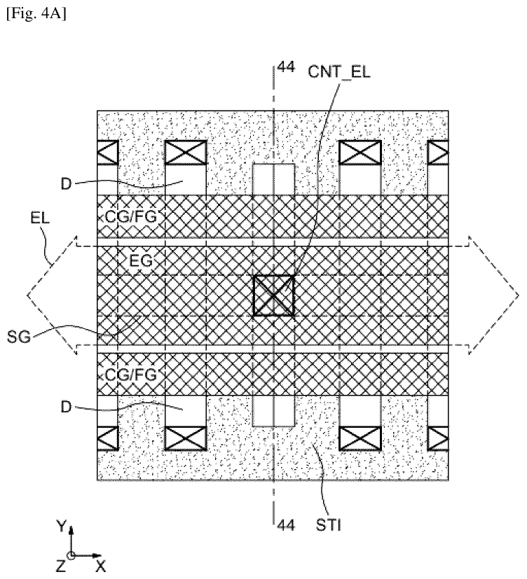

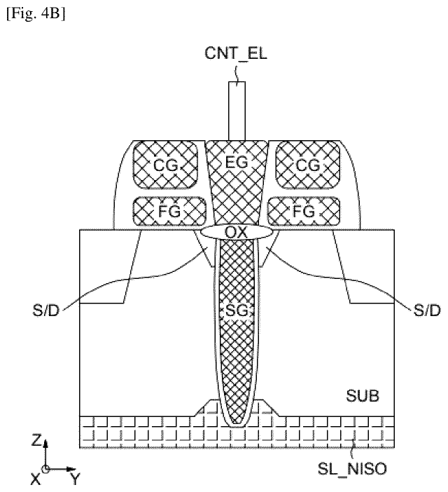

FIG. 4A shows a top view, in a plane XY, of the memory plane at a position of a contact socket CNT_EL of an erase line EL.

The erase lines EL are for example materialised by the erase gates EG common to the state transistors TE, traversing the memory plane in the second direction X, in a mutualised manner for a group of memory cells, for example a row or a word.

FIG. 4B illustrates a sectional view of the memory plane, in the plane YZ marked by the axis 44 in FIG. 4A passing through the erase line contact CNT_EL.

The erase line contact sockets CNT_EL, for example, are metal pillars for connecting the erase gate EG to metal tracks of the “BEOL” interconnection levels, to route the erase control signals S_ER in particular.

For example, the erase line contact sockets CNT_EL may be disposed every 9 μm (micrometres) in the second direction X.

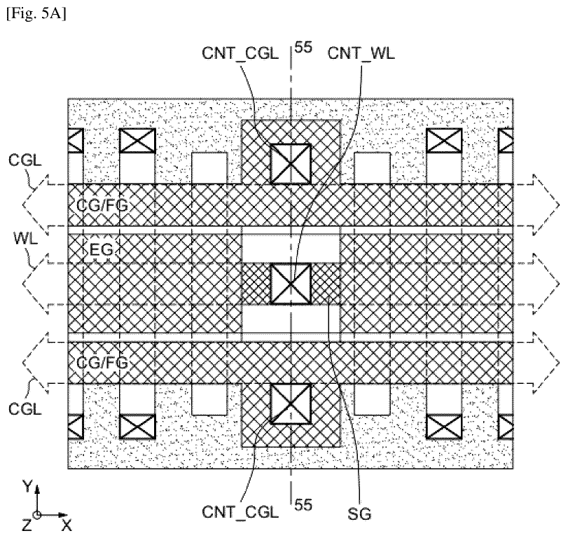

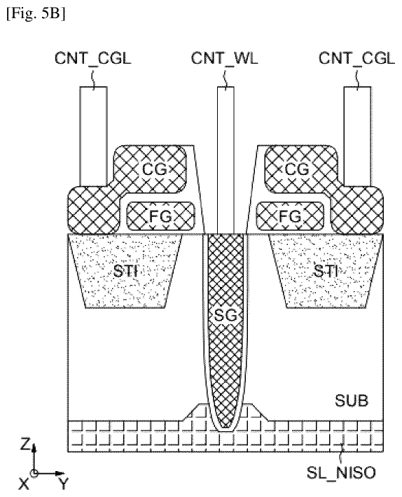

FIG. 5A shows a top view, in an XY plane, of the memory plane at a position of a contact socket CNT_CGL of a control gate line CGL.

The control gate lines CGL are for example materialised by the control gates CG of the state transistors TE, traversing the memory plane in the second direction X, mutually for a group of memory cells, for example a row or a word.

FIG. 5B illustrates a sectional view of the memory plane, in the plane YZ marked by the axis 55 in FIG. 5A passing through the control gate line contacts CNT_CGL.

The control gate line contact sockets CNT_CGL, for example, are metal pillars for connecting the control gate CG to metal tracks of the “BEOL” interconnection levels, to route the erase control signals S_ER and programming signals S_PR.

For example, the contact sockets of control gate lines CNT_CGL may be disposed every 37 μm (micrometres) in the second direction X.

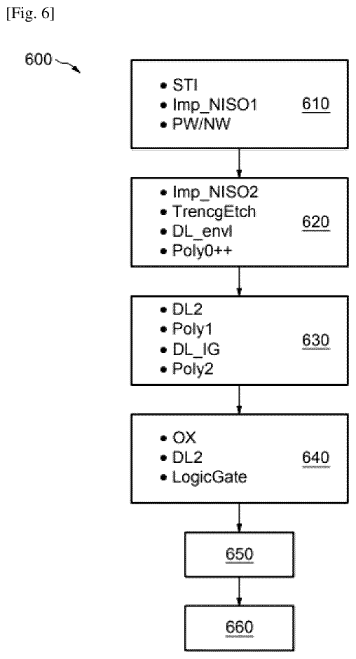

Reference is now made to FIG. 6.

FIG. 6 illustrates a method for manufacturing the non-volatile memory integrated circuit 600 including memory cells as previously described in relation to FIGS. 1 to 5B.

The method 600 comprises preliminary steps 610 comprising in particular forming the lateral isolation regions STI, implanting Imp_NISO1 a first deep-implanted region, and implanting the dopants of the P-type and N-type PW/NW wells.

The method 600 comprises steps 620 of forming the select transistor TS of the memory cells, including in particular an implantation Imp_NISO2 of a second deep-implanted region, forming, with the first, said deep-conducting region SL-NISO; an etching of a trench TrenchEtch extending vertically in the semiconductor substrate below the front face FA; a formation of a dielectric envelope DL_envl on the flanks and the bottom of the trench TrenchEtch; and a filling of the volume of the trench TrenchEtch with Poly0++ polycrystalline silicon, advantageously having a dopant concentration which is greater than 1019 cm-3.

The method 600 comprises steps 630 of forming the state transistor TE of the memory cells, including in particular forming the first dielectric layer DL1 on the front face FA of the substrate SUB; forming the floating polycrystalline silicon gate Poly1 on the first dielectric layer DL1; forming the inter-metal dielectric DL_IG between the floating gate and the control gate; and forming the polycrystalline silicon control gate Poly2 above the floating gate.

The method 600 comprises steps 640 of forming the erase gate EG of the memory cells, including in particular forming the dielectric thickness OX capable of electrically separating the erase gate and the vertical gate; forming a second dielectric layer DL2 bordering a flank of the floating gate opposite to the erase gate; and forming the erase gate, for example with the same implementation as logic gates LogicGate, positioned so as to be laterally opposite to the floating gate, and vertically above the vertical gate of the select transistor.

The method 600 comprises steps 650 of forming the “BEOL” interconnection portion including in particular the formations of the bit lines BL (see FIGS. 3A-5B), of the control gate lines CGL (see FIGS. 5A, 5B), of the erase lines EL (see FIGS. 4A, 4B), and of the word lines WL (see FIGS. 3A-3B).

The method 600 comprises steps 660 for example during a phase of characterising the product (usually “EWS” for “Electrical Wafer Sorting”) or during a use of the product, comprising at least one programming operation as previously described in relation to FIG. 2A, and at least one erase operation as previously described in relation to FIG. 2B.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A non-volatile memory integrated circuit, comprising:
two memory cells, each of the two memory cells including a state transistor having a control gate and a floating gate so that the two memory cells comprises two state transistors with two control gates and two floating gates, the two memory cells comprising a erase gate and a select transistor, the select transistor comprising a vertical gate buried in the semiconductor substrate,
the select transistor being common to the state transistors arranged on either side of the vertical gate, and
the erase gate being common to the two state transistors arranged on either side of the erase gate.

2. The integrated circuit according to claim 1, wherein the vertical gate and the erase gate are superimposed.

3. The integrated circuit according to claim 1, wherein the erase gate is located between the two control gates of the two state transistors and between the two floating gates of the two state transistors.

4. The integrated circuit according to claim 1, wherein the two memory cells are symmetrical to each other with respect to a plane passing through the erase gate and the vertical gate.

5. The integrated circuit according to claim 1, wherein each of the two control gates is disposed above a corresponding one of the two floating gates and the erase gate is disposed laterally opposite to the floating gate, a gate structure of the state transistor being disposed above a front face of the semiconductor substrate; and the buried vertical gate select transistor is disposed in the semiconductor substrate below the front face.

6. The integrated circuit according to claim 1, wherein the floating gate is bordered by a first dielectric layer opposite to the semiconductor substrate, and by a second dielectric layer opposite to the erase gate.

7. The integrated circuit according to claim 1, wherein the vertical gate of the select transistor and the erase gate of the state transistor have vertically aligned positions and are electrically separated by a dielectric thickness.

8. The integrated circuit according to claim 1, wherein the vertical gate of the select transistor includes polycrystalline silicon doped with a concentration which is greater than 10¹⁹ cm⁻³.

9. The integrated circuit according to claim 1, wherein the memory cells are arranged in a memory plane, traversed in a first direction by bit lines coupled to drain regions of the state transistors; and traversed in a second direction by control gate lines comprising the control gates of the state transistors, erase lines comprising the erase gates of the state transistors, and word lines comprising the vertical gates of the select transistors.

10. The integrated circuit according to claim 9,
wherein the control gate lines further comprise metal tracks for routing the erase and programming control signals and control gate line contact sockets coupling the control gates with the metal tracks;
wherein the erase lines further comprise metal tracks for routing the erase control signals and the erase line contact sockets coupling the erase gates with the metal tracks; and
wherein the word lines further comprise metal tracks for routing the control signals of the select transistors and word line contact sockets coupling the vertical gates with the metal tracks.

11. The integrated circuit according to claim 10, wherein the word line contact sockets are periodically disposed in the first direction with a first deviation;
wherein the erase line contact sockets are periodically disposed in the first direction with the first deviation; and wherein the control gate lines contact sockets are periodically disposed in the first direction with a second deviation; the first deviation being 3 to 5 times smaller than the second deviation.

12. A method for manufacturing a non-volatile memory integrated circuit including at least two memory cells, the method comprising:
forming a vertical gate select transistor buried in a semiconductor substrate, the select transistor comprising a vertical gate;
forming a first state transistor for a first of the memory cells and a second state transistor for a second of the memory cells, each of the first and second state transistors having a control gate and a floating gate, the select transistor being common to the first and second state transistors arranged on either side of the vertical gate; and
forming an erase gate of the first and second state transistors, the erase gate being common to the first and second state transistors arranged on either side of the erase gate.

13. The method according to claim 12, wherein:
forming the vertical gate select transistor comprises etching a trench extending vertically in the semiconductor substrate below a front face of the substrate;
forming the state transistor comprises forming the floating gate above the front face of the substrate, and forming the control gate above the floating gate; and
forming the erase gate of the state transistor comprises positioning the erase gate laterally facing the floating gate, above the front face of the semiconductor substrate.

14. The method according to claim 12, wherein:
forming the state transistor comprises forming a first dielectric layer, bordering the floating gate opposite to the substrate; and
forming the erase gate of the state transistor comprises forming a second dielectric layer, bordering the floating gate opposite to the erase gate.

15. The method according to claim 12, wherein:
forming the erase gate of the state transistor comprises forming a dielectric thickness electrically separating the erase gate and the vertical gate of the select transistor, the erase gate being aligned vertically on the vertical gate.

16. The method according to claim 12, wherein:
forming the select transistor comprises forming the vertical gate with polycrystalline silicon doped with a concentration greater than 10¹⁹ cm⁻³.

17. The method according to claim 12, further comprising, by a write circuit in the memory cells: a programming operation injecting electrical charges circulating through a channel region of the select transistor, into the floating gate of the state transistor; and an erase operation extracting electrical charges from the floating gate to the erase gate.

18. A method for manufacturing a non-volatile memory integrated circuit including at least two memory cells, the method comprising:
forming a vertical gate select transistor buried in a semiconductor substrate, the select transistor comprising a vertical gate;
forming a first state transistor for a first of the memory cells and a second state transistor for a second of the memory cells, each of the first and second state transistors having a control gate and a floating gate, the select transistor being common to the first and second state transistors arranged on either side of the vertical gate; and
forming an erase gate of the first and second state transistors, the erase gate being common to the first and second state transistors arranged on either side of the erase gate, wherein the memory cells are arranged in a memory plane;
forming bit lines traversing the memory plane in a first direction, the bit lines coupled to drain regions of the first and second state transistors;
forming control gate lines comprising the control gates of the first and second state transistors;
forming an erase line comprising the erase gate of the first and second state transistors; and
forming word lines traversing the memory plane in a second direction, the word lines comprising the vertical gates of the select transistors.

19. The method according to claim 18,
wherein the control gate lines further comprise metal tracks for routing the erase and programming control signals and control gate line contact sockets coupling the control gate with the metal tracks;
wherein the erase line further comprise a metal track for routing the erase control signals and erase line contact sockets coupling the erase gates with the metal tracks; and
wherein the word lines further comprise metal tracks for routing the control signals of the select transistors and the word line contact sockets coupling the vertical gates with the metal tracks.

20. The method according to claim 19, wherein the word line contact sockets are periodically formed in the first direction with a first deviation; wherein the erase line contact sockets are periodically formed in the first direction with the first deviation; and wherein the control gate line contact sockets are periodically formed in the first direction with a second deviation; the first deviation being 3 to 5 times smaller than the second deviation.
